(19) United States
(12) Patent Application Publication
(10) Pub. No.: US 2019/0204496 A1
(43) Pub. Date: Jul. 4, 2019

(54) BACKLIGHT UNIT AND DISPLAY DEVICE INCLUDING THE SAME

(71) Applicant: SAMSUNG DISPLAY CO., LTD., Yongin-si (KR)

(72) Inventors: KWANGKEUN LEE, Osan-si (KR); Junghyun Kwon, Seoul (KR); Yongseok Kim, Seoul (KR); Haeil Park, Seoul (KR); Seon-Tae Yoon, Seoul (KR); Daeho Lee, Seoul (KR)

(21) Appl. No.: 16/238,313

(22) Filed: Jan. 2, 2019

(30) Foreign Application Priority Data
Jan. 3, 2018 (KR) 10-2018-0000840

(51) Int. Cl. F21V 8/00; H05K 5/00; G09G 3/22

(52) U.S. Cl. CPC G02B 6/0026; G02B 6/0066; G09G 3/22; H05K 5/0017; G02B 6/004

(57) ABSTRACT

A backlight unit includes a light guide plate that includes a side surface that is an incidence surface that is normal to a first direction, a light source adjacent to the incidence surface, and a light conversion layer disposed on an upper surface of the light guide plate that changes a wavelength of light incident thereto. The light conversion layer includes a first portion and a second portion arranged in the first direction. The first portion is closer to the incidence surface in the first direction than the second portion, and the first portion is thinner than the second portion.

### CROSS-REFERENCE TO RELATED APPLICATIONS

This U.S. non-provisional patent application claims priority under 35 U.S.C. § 119 from, and the benefit of, Korean Patent Application No. 10-2018-0000840, filed on Jan. 3, 2018 in the Korean Intellectual Property Office, the contents of which are herein incorporated by reference in their entirety.

### BACKGROUND

Embodiments of the present disclosure are directed to a display device, and in particular, to a display device with improved display quality.

A next-generation advanced display device with low power consumption, good portability, and high added-value properties has recently come into the spotlight. Such a display device includes a plurality of pixels, and each pixel includes a thin-film transistor that controls a switching operation or a voltage to be supplied to each pixel.

A display device includes a display panel and a backlight unit that provides light to the display panel. The backlight unit includes a light source and a light guide plate. Light generated by the light source is incident into the light guide plate and is then provided to the display panel.

### SUMMARY

Some embodiments of the inventive concept provide a display device with improved display quality.

According to some embodiments of the inventive concept, a backlight unit includes a light guide plate that includes a side surface that is an incidence surface that is normal to a first direction, a light source adjacent to the incidence surface, and a light conversion layer disposed on an upper surface of the light guide plate that changes a wavelength of light incident thereto. The light conversion layer includes a first portion and a second portion arranged in the first direction. The first portion is closer to the incidence surface in the first direction than the second portion, and the first portion is thinner than the second portion.

In some embodiments, the second portion has a uniform thickness.

In some embodiments, the first portion has a uniform thickness.

In some embodiments, when measured in the first direction, a length of the first portion is less than about 5% of a length of the light guide plate.

In some embodiments, the first portion is connected to the second portion.

In some embodiments, a top surface of the first portion includes an inclined surface in which a thickness of the first portion increases in a direction from the incidence surface toward the second portion.

In some embodiments, the light conversion layer includes a plurality of quantum dots.

According to some embodiments of the inventive concept, a backlight unit includes a light guide plate that includes a side surface that is an incidence surface that is normal to a first direction; a light source adjacent to the incidence surface that generates a first light toward the incidence surface; and a light conversion layer disposed on an upper surface of the light guide plate that changes a wavelength of light incident thereto. The light conversion layer includes a plurality of first quantum dots that convert the first light into a second light that has a different wavelength range from that of the first light and a plurality of second quantum dots that convert the first light into a third light that has a different wavelength range from those of the first and second lights.

In some embodiments, the first light is a blue light.

In some embodiments, the light conversion layer includes a first portion and a second portion arranged in the first direction. A number of quantum dots per unit volume in the first portion is less than that in the second portion.

In some embodiments, the number of quantum dot per unit volume in the first portion increases in a direction from the incidence surface toward the second portion.

In some embodiments, the first portion is closer to the incidence surface in the first direction than the second portion, and the first portion is thinner than the second portion.

In some embodiments, the first portion includes a plurality of patterns that are spaced apart from each other in the first direction when viewed in a plan view. A distance between adjacent patterns of the plurality of patterns decreases in a direction from the incidence surface toward the second portion.

In some embodiments, the backlight unit further includes a low refraction layer interposed between the light guide plate and the light conversion layer. A refractive index of the low refraction layer is less than those of the light guide plate and the light conversion layer.

In some embodiments, the backlight unit further includes a scattering member disposed on the second portion that includes a plurality of scattering objects. The scattering member does not overlap the first portion, when viewed in a plan view.

According to some embodiments of the inventive concept, a backlight unit includes a light guide plate that includes a side surface that is an incidence surface, and a light conversion layer disposed on the light guide plate, the light conversion layer including a plurality of quantum dots that convert a first light into light that has a different wavelength range from that of the first light. The light conversion layer includes a first region and a second region arranged in a direction. The first region is closer to the incidence surface than the second region, and a thickness of the light conversion layer in the first region is less than that in the second region.

In some embodiments, the backlight unit further includes a light source adjacent to the incidence surface that emits the first light toward the incidence surface. The plurality of quantum dots include a plurality of first quantum dots that convert the first light to a second light having a different wavelength range from that of the first light; and a plurality of second quantum dots that convert the first light to a third light having a different wavelength range from those of the first and second lights.

In some embodiments, an area of a top surface of the first region is less than about one-twentieth of a total area of a top surface of the light guide plate.

In some embodiments, the light conversion layer in the second region has a uniform thickness.

In some embodiments, a thickness of the light conversion layer in the first region increases in a direction from the incidence surface toward the second region.

### BRIEF DESCRIPTION OF THE DRAWINGS

FIG. 1 is an exploded perspective view of a display device according to some embodiments of the inventive concept.

FIG. 2 is a sectional view taken along line I-I′ of FIG. 1.

FIG. 3 is a sectional view of a backlight unit according to some embodiments of the inventive concept.

FIG. 4 is a top plan view of a backlight unit according to some embodiments of the inventive concept.

FIG. 5 is an enlarged sectional view of a portion ‘A’ of FIG. 2.

FIG. 6 is a sectional view of a backlight unit according to other embodiments of the inventive concept.

FIG. 7 illustrates propagation paths of light emitted from a light source according to other embodiments of the inventive concept.

FIG. 8 is a sectional view of a backlight unit according to other embodiments of the inventive concept.

FIG. 9 is a top plan view of a backlight unit according to other embodiments of the inventive concept.

FIG. 10 is a sectional view of a backlight unit according to other embodiments of the inventive concept.

FIG. 11 is a sectional view of a backlight unit according to other embodiments of the inventive concept.

It should be noted that these drawings are not to scale and may not precisely reflect the precise structural or performance characteristics of any given embodiment. The use of similar or identical reference numbers in the various drawings may indicate the presence of a similar or identical element or feature.

### DETAILED DESCRIPTION

Exemplary embodiments of the inventive concepts will now be described more fully with reference to the accompanying drawings, in which example embodiments are shown. Exemplary embodiments of the inventive concepts may, however, be embodied in many different forms and should not be construed as being limited to the embodiments set forth herein. In the drawings, the thicknesses of layers and regions may be exaggerated for clarity. Like reference numerals in the drawings may denote like elements, and thus their description will be omitted.

It will be understood that when an element is referred to as being “connected” or “coupled” to another element, it can be directly connected or coupled to the other element or intervening elements may be present.

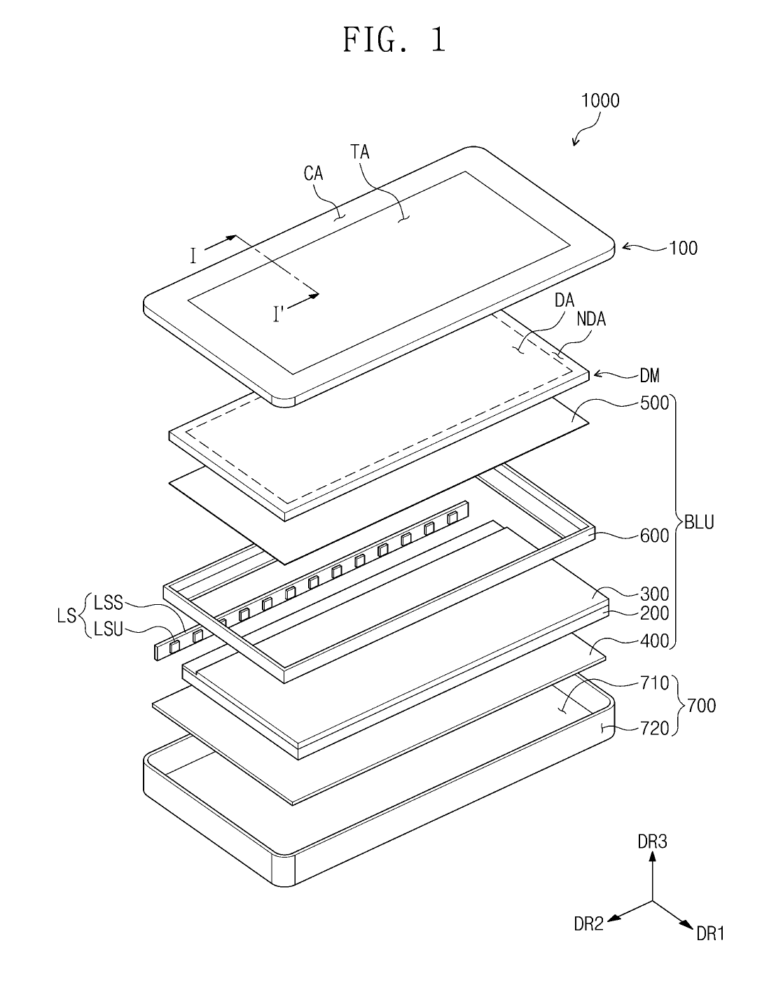

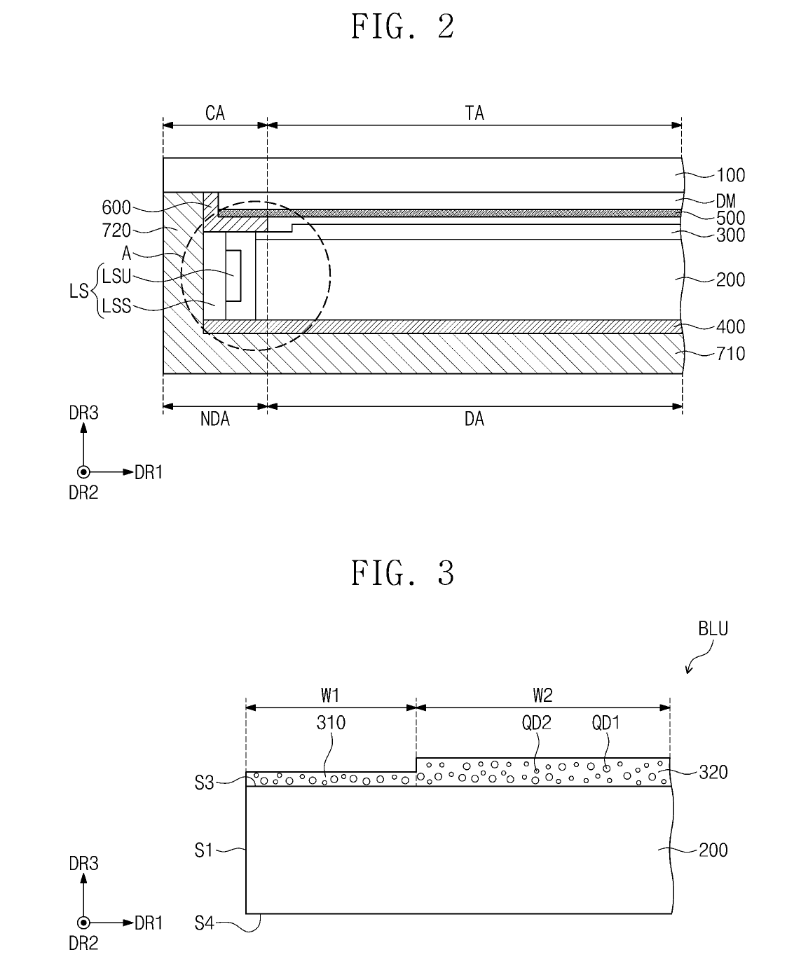

FIG. 1 is an exploded perspective view of a display device according to some embodiments of the inventive concept, and FIG. 2 is a sectional view taken along line I-I of FIG. 1.

Referring to FIGS. 1 and 2, a display device 1000 according to some embodiments of the inventive concept has a rectangular shape whose short sides are parallel to a first direction DR1 and whose long sides are parallel to a second direction DR2. However, embodiments of the inventive concept are not limited to a specific shape of the display device 1000, and the display device 1000 may have various other shapes.

According to some embodiments the display device 1000 includes a window member 100, a display panel DM, a backlight unit BLU, and a storage member 700.

For convenience in description, a propagation direction of image or light in the display device 1000 will be referred to as an upward direction, and a direction opposite to the upward direction will be referred to as a downward direction. In a present embodiment, the upward and downward directions are defined to be parallel to a third direction DR3 that is orthogonal to the first and second directions DR1 and DR2. Hereinafter, front and rear surfaces of each of elements to be described below will be differentiated based on the third direction DR3. However, the upward and downward directions are a relative concept, and in certain embodiments, they may be used to indicate other directions.

According to some embodiments, the window structure 100 includes a light-transmitting region TA that allows image light emitted from the display panel DM to pass therethrough, and a light-blocking region CA adjacent to the light-transmitting region TA that prevents image light from passing therethrough. When viewed in a plane defined by the first and second directions DR1 and DR2, the light-transmitting region TA is positioned at a center region of the display device 1000. The light-blocking region CA is provided at a peripheral region of the light-transmitting region TA and surrounds the light-transmitting region TA. For example, the light-blocking region CA has a frame shape.

According to some embodiments, the window member 100 is formed of or includes at least one of glass, sapphire, or plastic.

According to some embodiments, the display panel DM is disposed below the window member 100. The display panel DM displays an image using light emitted from the backlight unit BLU. In other words, the display panel DM is a light-receiving type display panel. For example, in some embodiments, the display panel DM is a liquid crystal display panel.

According to some embodiments, a surface of the display panel DM that displays an image will be referred to as a display surface. The display surface includes a display region DA which is used to display an image, and a non-display region NDA in which no image is displayed. When viewed in a plan view, the display region DA is a center region of the display panel DM and overlaps the light-transmitting region TA of the window member 100.

According to some embodiments, the backlight unit BLU is disposed below the display panel DM and is used to provide light to the display panel DM. In a present embodiment, the backlight unit BLU is an edge-type backlight unit.

According to some embodiments, the backlight unit BLU includes a light source LS, a light guide plate 200, a light conversion layer 300, a reflection sheet 400, an optical member 500, and a mold frame 600.

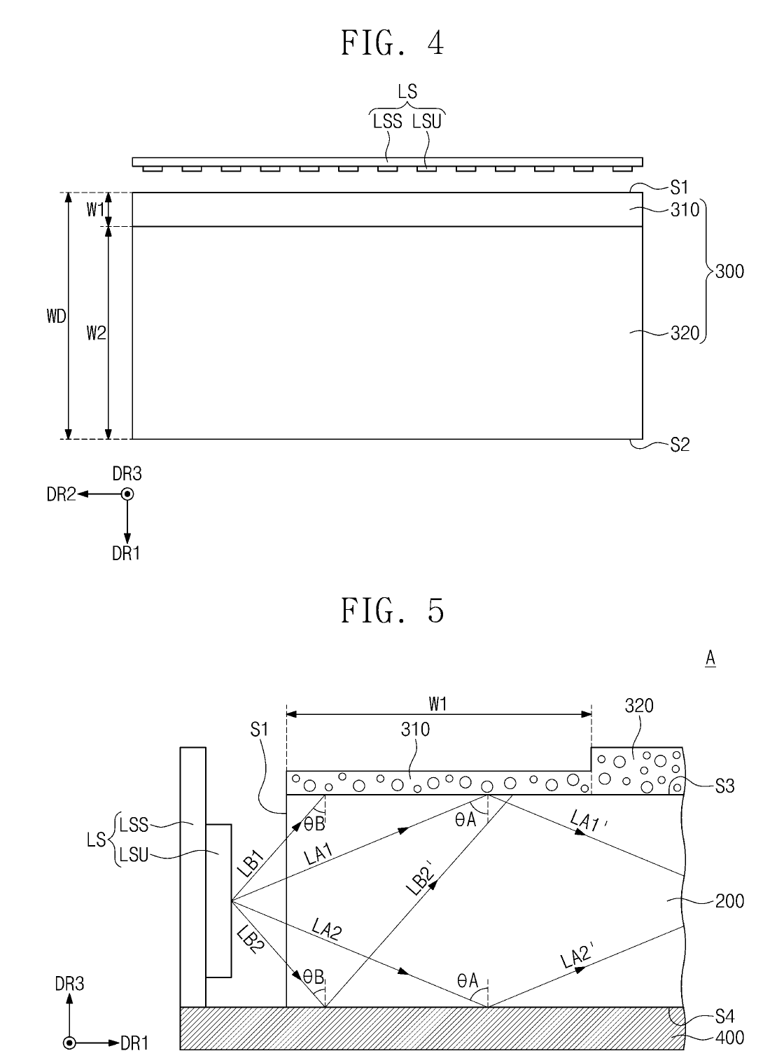

According to some embodiments, the light source LS is disposed adjacent in the first direction DR1 to at least one side surface of the light guide plate 200. However, embodiments of the inventive concept are not limited to a specific position of the light source LS, and, for example, the light source LS can be provided adjacent to at least one other side surface of the light guide plate 200. The side surface of the light guide plate 200 adjacent to the light source LS may be referred to as a first surface S1 (e.g., see FIGS. 3 and 4).

According to some embodiments, light source LS includes a plurality of light source units LSU and a light source substrate LSS.

According to some embodiments, the light source units LSU can generate light which is provided to the display panel DM through the light guide plate 200.

In a present embodiment, the light source units LSU generate a first light. For example, the first light has a wavelength that ranges from about 400 nm to about 500 nm. In other words, the light source units LSU generate substantially blue light.

In a present embodiment, each of the light source units LSU is a point-like light source, such as a light emitting diode (LED). However, embodiments of the inventive concept are not limited to a specific kind of light source unit LSU.

Furthermore, embodiments of the inventive concept are not limited to the number of the light source units LSU. In some embodiments, the light source unit LSU is a single LED serving as a point-like light source or a plurality of LED groups. In other embodiments, the light source units LSU are a linear light source.

According to some embodiments, the light source units LSU is mounted on the light source substrate LSS. The light source substrate LSS faces a side surface of the light guide plate 200 in the first direction DR1 and extends in the second direction DR2. The light source substrate LSS includes a light source control unit that is connected to the light source units LSU. The light source control unit analyzes an image to be displayed on the display panel DM to output a local dimming signal based on the image analysis, and to control the brightness of light generated by the light source units LSU based on the local dimming signal. In some embodiments, the light source control unit is mounted on an additional circuit substrate, but embodiments of the inventive concept are not limited to a specific position of the light source control unit.

According to some embodiments, the light guide plate 200 has a plate shape. The light guide plate 200 redirects light received from the light source LS toward the display panel DM or in the upward direction.

According to some embodiments, the light guide plate 200 is formed of or includes a material having a high transmittance to visible light. For example, the light guide plate 200 is formed of or includes glass. In some embodiments, the light guide plate 200 is formed of or includes a transparent polymer resin, such as polymethyl methacrylate (PMMA).

According to some embodiments, the light guide plate 200 has a first refractive index. For example, the first refractive index ranges from about 1.4 to about 1.55.

According to some embodiments, the light conversion layer 300 is disposed on the light guide plate 200. In some embodiments, the light conversion layer 300 is formed on the top surface of the light guide plate 200 by a coating process. The light conversion layer 300 changes a wavelength of an incident light. The light conversion layer 300 has a second refractive index. For example, the second refractive index is equal to or greater than about 1.65. The light conversion layer 300 will be described in more detail with reference to FIGS. 3 to 5.

According to some embodiments, the reflection sheet 400 is disposed below the light guide plate 200. The reflection sheet 400 reflects light that has propagated toward a bottom surface of the light guide plate 200 in the upward direction. The reflection sheet 400 includes a light-reflective material. For example, the reflection sheet 400 is formed of or includes aluminum or silver.

According to some embodiments, the optical member 500 is disposed between the light conversion layer 300 and the display panel DM. The optical member 500 diffuses and condenses light received from the light conversion layer 300 and emits the light toward the display panel DM.

According to some embodiments, the optical member 500 includes a plurality of sheets. For example, the optical member 500 includes a diffusion sheet, a prism sheet, and a protection sheet. The diffusion sheet diffuses light received from the light conversion layer 300. The prism sheet is disposed on the diffusion sheet and condenses light diffused by the diffusion sheet and then emits the light in the upward direction.

According to some embodiments, the protection sheet protects prisms of the prism sheet against friction caused by external objects. However, embodiments of the inventive concept are not limited to the number or types of sheets in the optical member 500.

According to some embodiments, the mold frame 600 is disposed between the light guide plate 200 and the optical member 500. In a present embodiment, the mold frame 600 has a frame shape. For example, the mold frame 600 is disposed along an edge region of the top surface of the light guide plate 200. The display panel DM and the optical member 500 are placed on the mold frame 600. The mold frame 600 fixes and holds the display panel DM, the optical member 500, and the backlight unit BLU.

According to some embodiments, the storage member 700 is disposed at a lowermost level of the display device 1000 and contains the backlight unit BLU. The storage member 700 includes a bottom portion 710 and a plurality of sidewall portions 720 that are connected to the bottom portion 710. In some embodiments, the light source LS is disposed on an inner side surface of one of the sidewall portions 720 of the storage member 700. The storage member 700 is formed of or includes a sufficiently hard metal.

FIG. 3 is a sectional view of a backlight unit according to some embodiments of the inventive concept, and FIG. 4 is a top plan view of a backlight unit according to some embodiments of the inventive concept. For convenience in illustration, those elements of a backlight unit other than a light guide plate and a light conversion layer are omitted from FIG. 3.

Referring to FIGS. 3 and 4, according to some embodiments, the light conversion layer 300 includes a plurality of conversion particles. Each of the conversion particles absorbs at least a portion of the incident light and then emits light with a different color from that of the incident light, or transmits the portion of incident light without a change in color.

According to some embodiments, when the energy of light incident into the light conversion layer 300 is high enough to excite a conversion particle, the conversion particle absorbs at least a portion of the incident light, thereby transitioning into an excited state, and then when it decays back to a stable or low-energy state, light whose color differs from that of the incident light is emitted from the conversion particle. By contrast, when the energy of the incident light is too low to excite the conversion particle, the incident light passes through the light conversion layer 300 without a change in color.

According to some embodiments, the color of light emitted from the conversion particle is determined by a particle size of the conversion particle. In general, the larger the particle size, the longer the wavelength of the emitted light, and the smaller the particle size, the shorter the wavelength of the emitted light.

In a present embodiment, each of the conversion particles is a quantum dot (QD). Light emitted from the conversion particles of the light conversion layer 300 are radiated in various directions.

For example, according to some embodiments, the conversion particles include first quantum dots QD1 and second quantum dots QD2. Each of the first quantum dots QD1 converts the first light into a second light by absorbing the first light and then emitting the second light. For example, the second light has a wavelength that ranges from about 640 nm to about 780 nm. In other words, each of the first quantum dots QD1 coverts a substantially blue light to red light.

According to some embodiments, each of the second quantum dots QD2 converts the first light to a third light by absorbing the first light and then emitting the third light. For example, the third light has a wavelength that ranges from about 480 nm to about 560 nm. In other words, each of the second quantum dots QD2 converts a substantially blue light to green light.

As described above, according to some embodiments, the wavelength of the converted light is determined by a particle size of the conversion particles. In a present embodiment, each of the first quantum dots QD1 has a particle size larger than that of each of the second quantum dots QD2.

According to some embodiments, the light conversion layer 300 may further include scattering objects. The scattering objects are mixed with the first and second quantum dots QD1 and QD2 in the light conversion layer 300.

In a present embodiment, the light conversion layer 300 includes a first region W1 and a second region W2. The first region W1 and the second region W2 are arranged in the first direction DR1. The first region W1 and the second region W2 are connected to each other. The first region W1 may be closer to the first surface S1 that is an incidence surface of the light guide plate 200 than the second region W2. In other words, the second region W2 is closer to a second, opposite surface S2 of the light guide plate 200 than the first region W1. The first surface S1 and the second surface S2 are opposite to each other in the first direction DR1.

In a present embodiment, the light conversion layer 300 includes a first portion 310 and a second portion 320. The first portion 310 corresponds to the first region W1, and the second portion 320 corresponds to the second region W2. In a present embodiment, the first portion 310 and the second portion 320 are connected to each other, thereby forming a single continuous object.

According to some embodiments, when measured in the first direction DR1, the first portion 310 has a first length and the second portion 320 has a second length. In some embodiments, the first length is shorter than about 5% of a total length WD of the light guide plate 200 in the first direction DR1. In other words, an area of the first region W1 is less than about one-twentieth of the total area of the light guide plate 200.

In some embodiments, the first portion 310 is thinner than the second portion 320. Each of the first portion 310 and the second portion 320 has a uniform thickness. The second portion 320 has a thickness of about 10 um. This will be described in more detail with reference to FIG. 5.

FIG. 5 is an enlarged sectional view of a portion ‘A’ of FIG. 2. FIG. 5 illustrates a propagation path of light emitted from the light source LS.

Referring to FIG. 5 in conjunction with FIGS. 3 and 4, according to some embodiments, light emitted by the light source units LSU propagates toward the light guide plate 200.

According to some embodiments, light that is incident to the light guide plate 200 is incident onto the top surface of the light guide plate 200 at an incidence angle that is greater than a critical angle when measured from a direction normal to the top surface of the light guide plate 200. In this case, total reflection of the incident light occurs at the top surface of the light guide plate 200. By contrast, when an incidence angle of the incident light is less than the critical angle, the incident light propagates through the light guide plate 200. The top surface of the light guide plate 200 is a light-emitting surface and, hereinafter is referred to as a third surface S3.

In detail, according to some embodiments, as shown in FIG. 5, light emitted from the light source LS that is incident to the light guide plate 200 includes a first upward incident light LA1 that is incident onto the third surface S3 of the light guide plate 200 at a first angle θA relative to a direction normal to the third surface S3. The first angle θA is greater than the critical angle. Thus, the first upward incident light LA1 is reflected by the third surface S3 back into the light guide plate 200, thereby forming first downward reflected light LA1′.

According to some embodiments, light emitted from the light source LS that is incident to the light guide plate 200 also includes a first downward incident light LA2 that is incident into a fourth surface S4 of the light guide plate 200 at the first angle θA relative to a direction normal to the fourth surface S4. The fourth surface S4 is a bottom surface of the light guide plate 200. Thus, the first downward incident light LA2 is reflected by the fourth surface S4 back into the light guide plate 200, thereby forming first upward reflected light LA1′.

According to some embodiments, light emitted from the light source LS that is incident to the light guide plate 200 includes a second upward incident light LB1 that is incident onto the third surface S3 of the light guide plate 200 at a second angle θB relative to the direction normal to the third surface S3. The second angle θB is less than the critical angle. Thus, the second upward incident light LB1 propagates through the third surface S3 of the light guide plate 200 and is incident into the light conversion layer 300. In other words, the second upward incident light LB1 propagates into the light conversion layer 300 without an internal redirection from the light guide plate 200.

According to some embodiments, light emitted from the light source LS that is incident to the light guide plate 200 also includes a second downward incident light LB2 that is incident onto the fourth surface S4 of the light guide plate 200 at the second angle θB relative to the direction normal to the fourth surface S4. Thereafter, the second downward incident light LB2 is reflected by the reflection sheet 400 or by the fourth surface S4 of the light guide plate 200. Such a second upward reflected light LB2′ is incident onto the third surface S3 of the light guide plate 200 at the second angle θB. Thus, the second upward reflected light LB2′ propagates through the third surface S3 of the light guide plate 200 and is incident into the light conversion layer 300. In other words, the second downward incident light LB2′ propagates into the light conversion layer 300 without an internal redirection from the light guide plate 200.

According to some embodiments, unlike an afore-described embodiment, when light, such as the second upward incident light LB1 or the second downward incident light LB2, is incident into the light guide plate 200 at the second angle θB less than the critical angle, it will be incident into the first portion 310 of the light conversion layer 300 without being reflected by the third surface S3 of the light guide plate 200. In other words, an amount of light per unit area incident into the first portion 310 is greater than an amount of light incident into the second portion 320. Thus, an amount of light to be converted by the first portion 310 is increased. This can reduce the brightness uniformity of the display device 1000. However, according to some embodiments of the inventive concept, since the first portion 310 of the light conversion layer 300 is thinner than the second portion 320, an amount of light converted by the first portion 310 is less than an amount of light converted by the second portion 320, thus maintaining the brightness uniformity of the display device 1000, even when an amount of light per unit area incident into the first portion 310 is greater than an amount of light per unit area incident into the second portion 320.

According to some embodiments of the inventive concept, incident light propagating from the light source LS toward the fourth surface S4 of the light guide plate 200 include critical light that is incident onto the fourth surface S4 at the critical angle, and here, the critical light is reflected by the reflection sheet 400 back toward the third surface S3. The first region W1 may be defined as that portion of the third surface S3 to which the critical light reflected by the fourth surface is incident. In other words, a length of the first portion 310 in the first direction DR1 is determined by the critical angle of the critical light. In some embodiments, the length of the first portion 310 is proportional to the critical angle of the critical light. In other embodiments, the length of the first portion 310 is determined based on an angle at which light is emitted from the light source units LSU, a distance between the light source unit LSU and the light guide plate 200, a thickness of the light guide plate 200, and a refractive index of the light guide plate 200.

As a result, according to some embodiments of the inventive concept, a display quality of the display device 1000 can be improved.

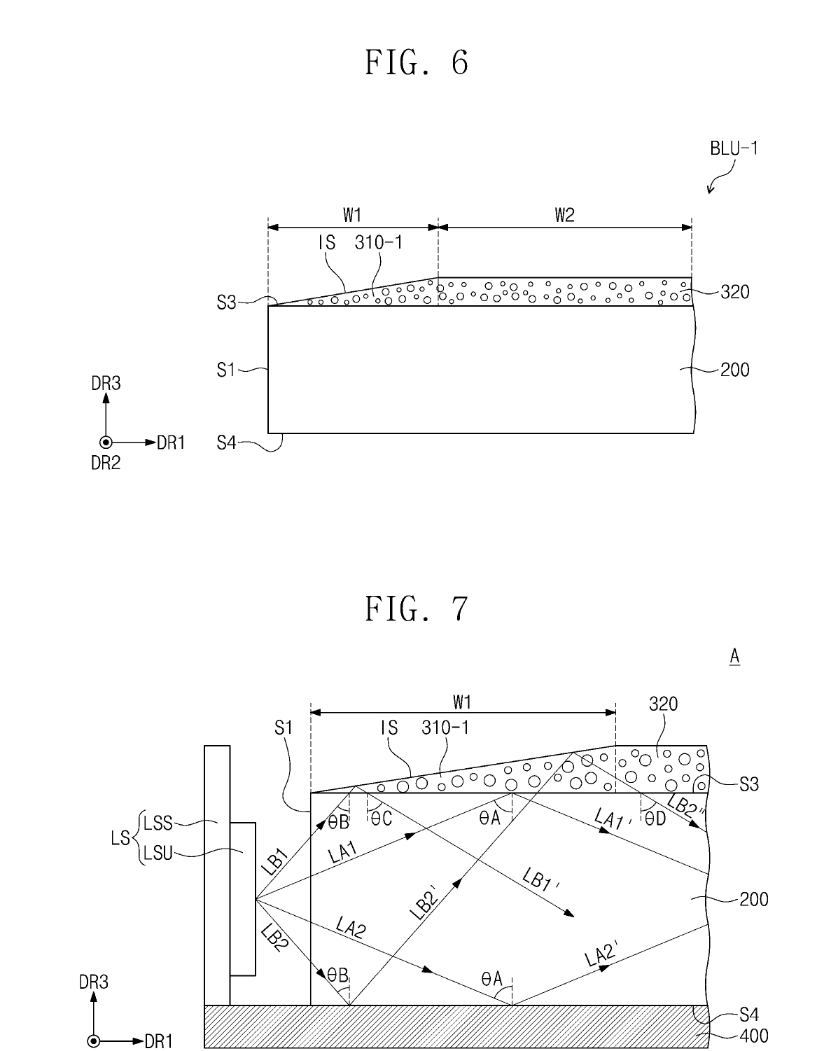

FIG. 6 is a sectional view of a backlight unit according to other embodiments of the inventive concept, and FIG. 7 illustrates propagation paths of light emitted from a light source according to other embodiments of the inventive concept.

For concise description, a previously described element may be identified by a similar or identical reference number without repeating a description thereof. Other elements that are not separately described may have substantially the same technical features as those in previously described embodiments.

For convenience in illustration, those elements of a backlight unit other than a light guide plate and a light conversion layer are omitted from FIG. 6.

Referring to FIG. 6, in a light conversion layer according to other embodiments of the inventive concept, a top surface of a first portion 310-1 includes an inclined surface IS. The inclined surface IS extends in the first direction DR1 and is inclined in a direction downward from the top surface of the second portion 320 toward the light source LS.

For example, in a present embodiment, the first portion 310-1 has a thickness that gradually decreases with increasing distance from the second portion 320.

Referring to FIG. 7, according to some embodiments, light emitted by the light source LS and incident to the light guide plate 200 includes the second upward incident light LB1 that is incident onto the third surface S3 of the light guide plate 200 at the second angle θB. The second angle θB is less than the critical angle. Thus, the second upward incident light LB1 propagates through the third surface S3 of the light guide plate 200 to be incident into the first portion 310-1. The second upward incident light LB1 incident into the first portion 310-1 is reflected by the inclined surface IS of the first portion 310-1, thereby forming a second downward reflected light LB1′ propagating toward the light guide plate 200. The second downward reflected light LB1′ is incident onto the third surface S3 at a third angle θC. Here, the third angle θC is greater than the critical angle, and in this case, the second downward reflected light LB1′ is re-incident into the light guide plate 200 through the third surface S3.

According to some embodiments, light emitted from the light source LS and incident to the light guide plate 200 includes the second downward incident light LB2 that is incident onto the fourth surface S4 of the light guide plate 200 at the second angle θB. The second downward incident light LB2 is reflected by the reflection sheet 400 or by the fourth surface S4 of the light guide plate 200 thereby forming a second upward reflected light LB2′. The second upward reflected light LB2′ is incident onto the third surface S3 of the light guide plate 200 at the second angle θB. Thus, the second upward reflected light LB2′ propagates through the third surface S3 of the light guide plate 200 and is incident into the first portion 310-1. The second upward reflected light LB2′ incident into the first portion 310-1 is reflected by the inclined surface IS of the first portion 310-1, thereby forming a third downward reflected light LB2″ that propagates toward the light guide plate 200. The third downward reflected light LB2″ has a fourth angle θD relative to the third surface S3 and the fourth surface S4. The fourth angle θD is greater than the critical angle, and in this case, the third downward reflected light LB2″ is re-incident into the light guide plate 200 through the third surface S3. In some embodiments, the fourth angle θD is substantially equal to the third angle θC, but embodiments of the inventive concept are not limited thereto.

In a present embodiment, since the top, inclined surface IS of the first portion 310-1 is inclined at an angle, even if light is incident into the first portion 310-1 at an incident angle less than the critical angle, the incident angle of the light relative to the normal to the inclined surface is of the first portion 310-1 may be increased. This makes it possible to prevent light from being concentrated in the first region W1 and can prevent structural differences between the first and second regions W1 and W2 from being recognized by a user.

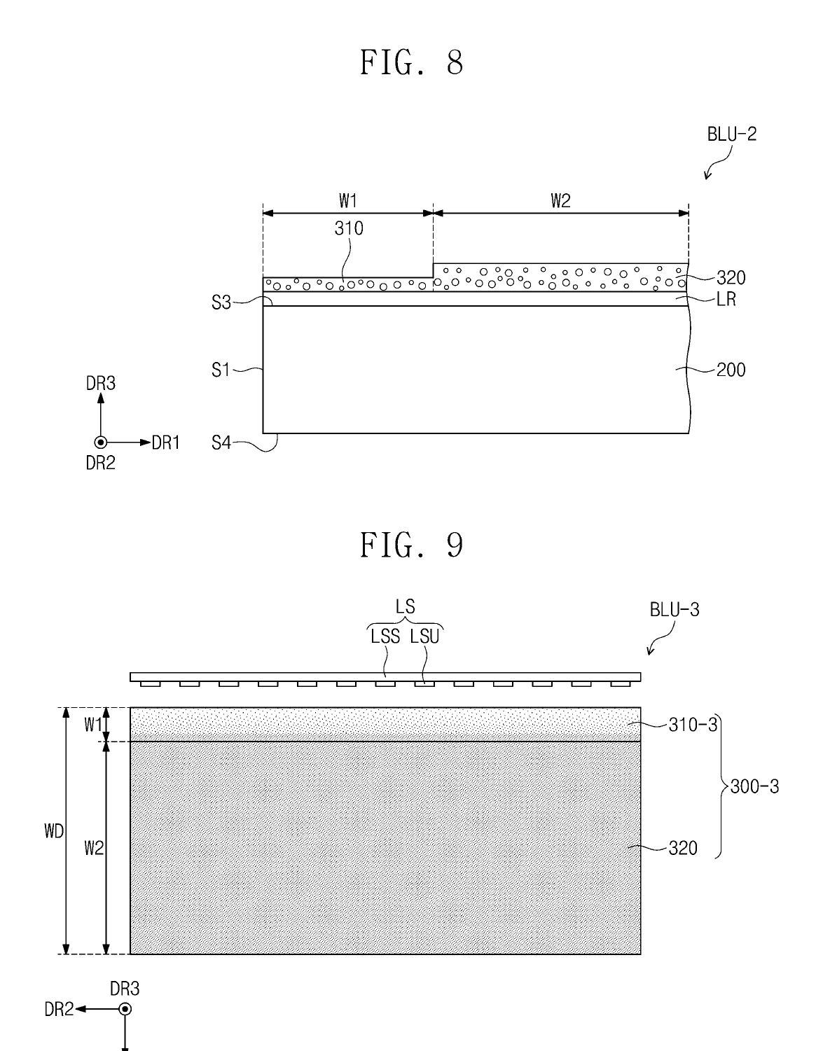

FIG. 8 is a sectional view of a backlight unit according to other embodiments of the inventive concept.

For concise description, a previously described element may be identified by a similar or identical reference number without repeating a description thereof. Other elements that are not separately described may have substantially the same technical features as those in the previously described embodiments.

Referring to FIG. 8, a backlight unit BLU-2 according to other embodiments of the inventive concept further includes a low refraction layer LR that is interposed between the light guide plate 200 and the light conversion layers 310 and 320. The low refraction layer LR has a third refractive index. In some embodiments, the third refractive index of the low refraction layer LR is less than those of the light guide plate 200 and the light conversion layer 310. For example, the third refractive index ranges from about 1.15 to about 1.35.

FIG. 9 is a top plan view of a backlight unit BLU-3 according to other embodiments of the inventive concept.

For concise description, a previously described element may be identified by a similar or identical reference number without repeating a description thereof. Other elements that are not separately described may have substantially the same technical features as those in the previously described embodiments.

Referring to FIG. 9, in a light conversion layer 300-3 according to other embodiments of the inventive concept, a number of quantum dots per unit volume in a first portion 310-3 is less than that in the second portion 320. Furthermore, the number of quantum dots per unit volume in the first portion 310-3 increases with decreasing distance from the second portion 320 or in the first direction DR1.

In a present embodiment, it is possible to effectively prevent the intensity of light from being locally increased at a specific region of the display device 1000, such as the first region W1.

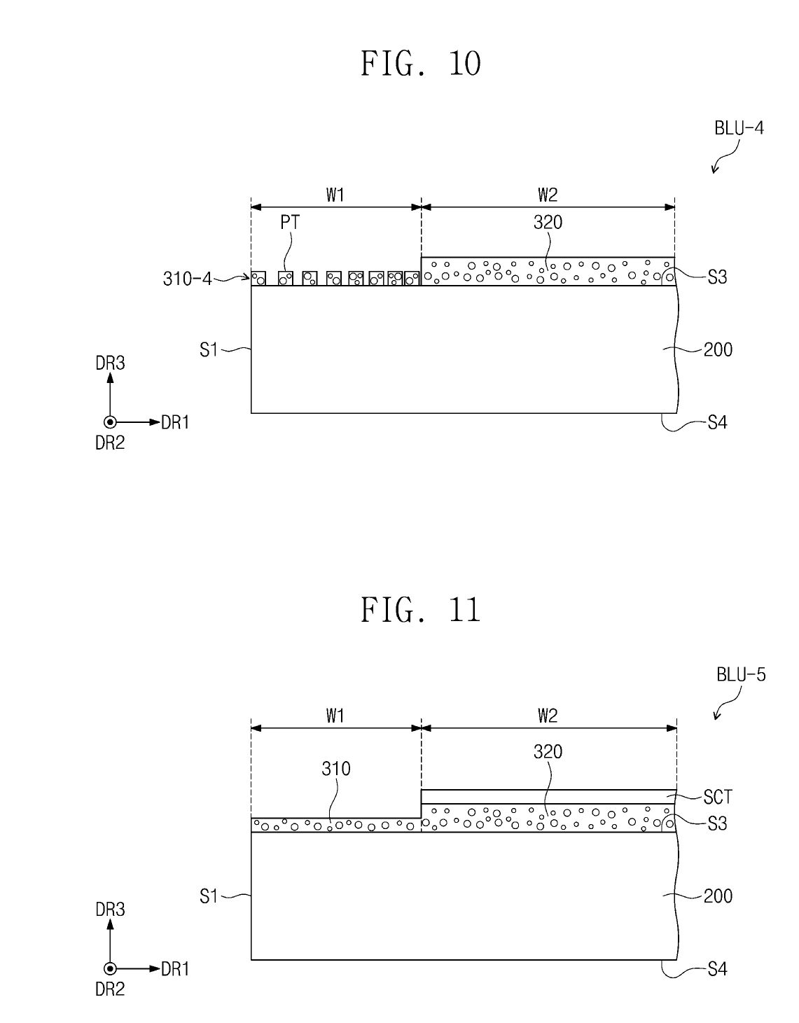

FIG. 10 is a sectional view of a backlight unit BLU-4 according to other embodiments of the inventive concept.

For concise description, a previously described element may be identified by a similar or identical reference number without repeating a description thereof. Other elements that are not separately described may have substantially the same technical features as those in the previously described embodiments.

Referring to FIG. 10, a light conversion layer according to other embodiments of the inventive concept includes a first portion 310-4 that includes a plurality of patterns PT. Each of the plurality of patterns PT includes at least one of the first and second quantum dots QD1 and QD2.

In a present embodiment, the plurality of patterns PT are spaced apart from each other in the first direction DR1. A distance in the first direction DR1 between adjacent pairs of the patterns PT decreases with decreasing distance from the second portion 320 or in the first direction DR1. In other words, the patterns PT have an increasing pattern density with decreasing distance from the second portion 320 or in the first direction DR1.

In a present embodiment, brightness uniformity of the display device 1000 can be effectively improved.

FIG. 11 is a sectional view of a backlight unit according to other embodiments of the inventive concept.

For concise description, a previously described element may be identified by a similar or identical reference number without repeating a description thereof. Other elements that are not separately described may have substantially the same technical features as those in the previously described embodiments.

Referring to FIG. 11, a backlight unit BLU-5 according to other embodiments of the inventive concept further includes a scattering member SCT disposed on the light conversion layer 300. The scattering member SCT includes a plurality of scattering objects that are configured to scatter incident light.

In a present embodiment, the scattering member SCT is disposed on the second portion 320. The scattering member SCT does not overlap the first portion 310, when viewed in a plan view.

According to some embodiments of the inventive concept, a display quality of a display device can be improved. For example, according to some embodiments of the inventive concept, brightness uniformity of the display device can be improved.

While exemplary embodiments of the inventive concepts have been particularly shown and described, it will be understood by one of ordinary skill in the art that variations in form and detail may be made therein without departing from the spirit and scope of the attached claims.

What is claimed is:

1. A display device, comprising:
a display panel configured to display an image;
a light guide plate provided below the display panel, the light guide plate including a side surface that is an incidence surface that is normal to a first direction;
a light source adjacent to the incidence surface; and
a light conversion layer disposed between the light guide plate and the display panel and configured to change a wavelength of light incident thereto,
wherein the light conversion layer comprises a first portion and a second portion arranged in the first direction,
the first portion is closer to the incidence surface in the first direction than the second portion, and
the first portion is thinner than the second portion.

2. The display device of claim 1, wherein the second portion has a uniform thickness.

3. The display device of claim 1, wherein the first portion has a uniform thickness.

4. The display device of claim 1, wherein, when measured in the first direction, a length of the first portion is less than about 5% of a length of the light guide plate.

5. The display device of claim 1, wherein the first portion is connected to the second portion.

6. The display device of claim 1, wherein a top surface of the first portion comprises an inclined surface.

7. The display device of claim 1, wherein a thickness of the first portion increases in a direction from the incidence surface toward the second portion.

8. The display device of claim 1, wherein the light conversion layer comprises a plurality of quantum dots.

9. The display device of claim 1, wherein the light source is configured to generate a first light, and
the light conversion layer comprises:
a first quantum dot converting the first light to a second light having a different wavelength range from that of the first light; and
a second quantum dot converting the first light to a third light having a different wavelength range from those of the first and second lights.

10. The display device of claim 9, wherein the first light is a blue light.

11. The display device of claim 9, wherein a number of quantum dots per unit volume in the first portion is less than that in the second portion.

12. The display device of claim 11, wherein the number of quantum dot per unit volume in the first portion increases in a direction from the incidence surface toward the second portion.

13. The display device of claim 1, wherein the first portion comprises a plurality of patterns that are spaced apart from each other in the first direction when viewed in a plan view, and
a distance between adjacent patterns of the plurality of patterns decreases in a direction from the incidence surface toward the second portion.

14. The display device of claim 1, further comprising a low refraction layer interposed between the light guide plate and the light conversion layer,
wherein a refractive index of the low refraction layer is less than those of the light guide plate and the light conversion layer.

15. The display device of claim 1, further comprising a scattering member disposed on an upper surface of the second portion that includes a plurality of scattering objects,
wherein the scattering member does not overlap the first portion, when viewed in a plan view.

16. A backlight unit, comprising:
a light guide plate that includes a side surface that is an incidence surface;
a light source provided adjacent to the incidence surface and configured to generate a first light; and
a light conversion layer disposed on the light guide plate, the light conversion layer comprising a plurality of quantum dots that convert the first light into light that has a different wavelength range from that of the first light,
wherein the light conversion layer includes a first region and a second region arranged in a direction,
the first region is closer to the incidence surface than the second region, and
a thickness of the light conversion layer in the first region is less than that in the second region.

17. The backlight unit of claim 16, wherein the plurality of quantum dots comprise:
a plurality of first quantum dots that convert the first light to a second light having a different wavelength range from that of the first light; and
a plurality of second quantum dots that convert the first light to a third light having a different wavelength range from those of the first and second lights.

18. The backlight unit of claim 16, wherein, an area of a top surface of the first region is less than about one-twentieth of a total area of a top surface of the light guide plate.

19. The backlight unit of claim 18, wherein the light conversion layer in the second region has a uniform thickness.

20. The backlight unit of claim 18, wherein a thickness of the light conversion layer in the first region increases in a direction from the incidence surface toward the second region.
